(19) United States
(12) Patent Application Publication
(10) Pub. No.: US 2010/0314620 A1
(43) Pub. Date: Dec. 16, 2010

(54) SEMICONDUCTOR DEVICE

(75) Inventors: Takeshi FURUSAWA, Kanagawa (JP); Takao Kamoshima, Kanagawa (JP); Hiroki Takewaka, Kanagawa (JP)

Correspondence Address: MILES & STOCKBRIDGE PC, 1751 PINNACLE DRIVE, SUITE 500, MCLEAN, VA, 22102-3833, US

(73) Assignee: RENESAS ELECTRONICS CORPORATION

(21) Appl. No.: 12/794,739

(22) Filed: Jun. 5, 2010

(30) Foreign Application Priority Data
Jun. 16, 2009 (JP) 2009-143133

(51) Int. Cl. H01L 23/48

(52) U.S. Cl. 257/48; 257/619; 257/734; 257/E23.01

(57) ABSTRACT

To suppress or prevent the generation of a crack in an insulating film below an external terminal which could be caused by an external force added to the external terminal of a semiconductor device. A top wiring layer MH of wiring layers formed on a main surface of a silicon substrate has a pad comprising a conductor pattern containing aluminum. On an undersurface of the pad, there are arranged a barrier conductor film formed by laminating, from below, a first barrier conductor film and a second barrier conductor film. Of a fifth wiring layer which is one layer lower than the top wiring layer, in an area overlapping with a probe contact area of the pad in a plane, the conductor pattern is not arranged. Further, the first and second barrier conductor films are the conductor films including titanium and titanium nitride as principal components, respectively. Also, the first barrier conductor film is thicker than the second barrier conductor film.

### CROSS-REFERENCE TO RELATED APPLICATIONS

The disclosure of Japanese Patent Application No. 2009-143133 filed on Jun. 16, 2009 including the specification, drawings and abstract is incorporated herein by reference in its entirety.

### BACKGROUND OF THE INVENTION

The present invention relates a semiconductor device, and more particularly, to a technology which suppresses or prevents the generation of a crack caused by an external force added to an external terminal of the semiconductor device in an insulating film below the external terminal.

In a manufacturing process of a semiconductor device, there is a probe inspection step of inspecting electric property of the semiconductor device by applying a probe to a bonding pad (hereafter, simply called a “pad”) which is an external terminal of a semiconductor chip formed on a semiconductor wafer. During such an inspection step, an external force (impact) added to the pad causes a crack in an insulating film below the pad, degrading reliability of the semiconductor device.

For example, Japanese Patent Laid-open No. 2007-123546 (Patent Document 1) discloses a semiconductor device comprising titanium (Ti) of 100 nm or more as a barrier metal between an aluminum (Al) pad and a copper (Cu) wiring, thereby preventing copper from permeating into the aluminum pad.

Further, for example, Japanese Patent Laid-open No. 2003-179059 (Patent Document 2) discloses a semiconductor device having, in a wiring pad portion, a barrier film formed by laminating two or more pairs of layers alternately and repeatedly, one of the pairs comprising a tantalum nitride (TaN) layer and a tantalum (Ta) layer, the other of the pairs comprising a titanium nitride (TiN) layer and a titanium layer. As a result, a barrier property and strength of the barrier film in the wiring pad portion as well as its reliability can be improved.

Further, for example, Japanese Patent Laid-open No. 2003-31575 (Patent Document 3) discloses, for a structure of an aluminum pad on a copper pad, a technique of embedding a connection via opening with a connection copper via to substantially flatten a stepped portion. As a result, a film of aluminum for forming the aluminum pad can be thinned. Thus, the production thereof can be made easier, and the copper pad can be prevented from being oxidized.

### [Patent Document 1] Japanese Patent Laid-open No. 2007-123546

### [Patent Document 2] Japanese Patent Laid-open No. 2003-179059

### [Patent Document 3] Japanese Patent Laid-open No. 2003-031575

### SUMMARY OF THE INVENTION

In recent years, in order to reduce an area of a semiconductor chip, elements and wiring have been liable to be arranged below a pad. As a result, at the time of probe inspection, there has come up a significant problem of how to prevent a crack from occurring in an insulating layer below the pad. Therefore, when arranging elements etc. below the pad, there are more and more needs for forming a stress-absorbing layer with use of the same material as a wiring layer immediately below the pad, or reinforcing with tungsten (W) whose elastic modulus is higher than that of SiO₂ and which is not plastically deformed easily or with a metal having a high melting point.

However, according to the investigation by the present inventors, when the stress-absorbing layer is formed immediately below the pad with the same metal (aluminum or copper) as the wiring layer, by the impact of a probe on the pad, the stress-absorbing layer is plastically deformed. Because of this, a crack occurs in an insulating layer in the wiring layer and is expanded to a lower layer. Further, the present inventors found that, even when using tungsten or a high-melting-point metal as a reinforcing layer, there were problems as follows. First, in a structure where the wiring layer (of aluminum or copper) lies immediately below tungsten or the high-melting-point metal, because of the plastic deformation of the wiring layer, a crack occurs in the tungsten or the high-melting-point metal, and is expanded to the lower layer. The wider the width of the wiring layer immediately below is, the greater the plastic deformation becomes. In a case where the size is substantially the same (30 to 100 μm) as the pad, the crack becomes particularly notable. Second, if there are a portion containing tungsten and a portion without tungsten, a crack occurs in an interface thereof and is expanded to the lower layer. Thirdly, when tungsten with high stress is formed thickly, the tungsten is peeled off because of the stress itself.

On the other hand, in the whole area, including a portion below the pad, inside the chip, it is common that, in a portion whose density of wiring patterns of each wiring layer is low, dummy patterns formed of a wiring material are arranged to adjust a pattern occupancy rate to a certain level or higher. The reason is that, if areas with low occupancy exist, there arises a difference between a high-occupancy area and a low-occupancy area during a CMP (Chemical and Mechanical Polishing) process, thereby causing a shift of focus of lithography in the layer higher than that.

When not arranging elements or wiring immediately below the pad, because of the above purpose, it is conceivable that dummy patterns might be arranged immediately below the pad. However, according to the investigation, the present inventors found that, when there was a dummy pattern immediately below the pad also, at the impact of a probe on the pad, the dummy pattern (wiring material) was plastically deformed to cause a crack in an insulating layer and the crack was expanded to a lower layer.

As described above, when there is a crack in the insulating film in the wiring layer, water enters therethrough, degrading reliability of devices and wiring. Further, because of a thermal stress after packaging, a force is applied to a wire bond and a bump, which may cause a problem that a pad portion is peeled and its line is broken, the crack portion being as a starting point.

Such a problem of the crack and peeling becomes prominent when a low-dielectric-constant film (Low-k film) having a low mechanical strength is used as an insulating film for the wiring layer.

On the other hand, as a method to suppress or prevent the above crack, a needle pressure of a probe is lowered during a probe inspection process. However, when the pressure of the needle is lowered, a contact resistance between the probe and the pad becomes greater. As a result of being unable to measure an electric property of a semiconductor device correctly, reliability of the semiconductor is degraded.

In view of the above, an object of the present invention is to provide a technology to suppress or prevent the generation of a crack in an insulating film underlying an external terminal caused by an external force added to the external terminal of a semiconductor device.

The above and other objects and novel features of the present invention will become apparent from the following description and the accompanying drawings.

A representative one of the inventions disclosed in the present application will be outlined in brief as follows.

The semiconductor device comprises wiring layers and connection layers alternately and repeatedly laminated so as to cover a main surface of a semiconductor substrate, each of the wiring layers having conductor patterns and an interlayer insulating film for insulation between the conductor patterns, each of the connection layers having a connection conductor piece for coupling the conductor patterns in the different wiring layers and the interlayer insulating films for insulation between the connection conductor pieces. A top layer of the wiring layers has an external terminal formed by the conductor pattern and a protective insulating film covering the external terminal, the external terminal comprising a conductor including aluminum as a principal component, the protective insulating film having an opening for allowing part of the external terminal to be exposed, the external terminal having a probe contact area in a part of the area exposed from the opening of the protective insulating film. The conductor pattern is not arranged in a portion overlapping with the probe contact area in a plane in a wiring layer which is one layer lower than the top wiring layer of the wiring layers. A barrier conductor film is arranged between the external terminal and the underlying interlayer insulating film, the barrier conductor film comprising a laminated film of a first barrier conductor film including titanium as a principal component and a second barrier conductor film including titanium nitride as a principal component, the first barrier conductor film being arranged on a side in contact with the interlayer insulating film and the second barrier conductor film being arranged on a side in contact with the external terminal, respectively. A thickness of the first barrier conductor film in a vertical direction is greater than that of the second barrier conductor film.

Advantageous effects obtained by a representative one of the inventions disclosed in the present application will be described in brief as follows.

That is, it becomes possible to suppress or prevent the generation of a crack in an insulating film underlying an external terminal caused by an external force added to the external terminal of a semiconductor device.

### BRIEF DESCRIPTION OF THE DRAWINGS

FIG. 1 is a plan view showing a principal part of a semiconductor device according to Embodiment 1 of the present invention;

FIG. 2 is a cross-sectional view showing the principal part of the semiconductor device, illustrating a cross-section taken along line A1-A1 in the plan view of FIG. 1 and viewed in the direction of arrows;

FIG. 3 is an enlarged cross-sectional view partially showing the principal part in FIG. 2;

FIG. 4 is an enlarged cross-sectional view partially showing the principal part in FIG. 3;

FIG. 5 is a plan view showing a principal part of another semiconductor device according to Embodiment 1 of the present invention;

FIG. 6 is a plan view showing a principal part of still another semiconductor device according to Embodiment 1 of the present invention;

FIG. 7 is a plan view showing a principal part of a semiconductor device according to Embodiment 2 of the present invention;

FIG. 8 is a cross-sectional view showing the principal part of the semiconductor device according to Embodiment 2 of the present invention;

FIG. 9 is an enlarged sectional view partially showing the principal part in FIG. 8;

FIG. 10 is a cross-sectional view showing a principal part of a semiconductor device according to Embodiment 3 of the present invention;

FIG. 11 is an enlarged cross-sectional view partially showing the principal part in FIG. 10;

FIG. 12 is a cross-sectional view showing a principal part of a semiconductor device according to Embodiment 4 of the present invention;

FIG. 13 is a cross-sectional view showing a principal part of a semiconductor device according to Embodiment 5 of the present invention;

FIG. 14 is a plan view showing a principal part of a semiconductor device according to Embodiment 6 of the present invention; and

FIG. 15 is a cross-sectional view showing the principal part of the semiconductor device, illustrating a cross-section taken along line A1-A1 in the plan view of FIG. 14 and viewed in the direction of arrows.

### DESCRIPTION OF THE PREFERRED EMBODIMENTS

In the embodiments described below; the description may be made with the subject matter divided in plural sections or in plural embodiments, if necessary for convenience's sake. These plural sections or embodiments are not independent of each other, but are in a relation such that one is a modification, example, a detailed or complementary description of a part or whole of the other one, unless otherwise specifically indicated. In the embodiments described below, when a reference is made to a number of elements (including a number, value, amount, and range), the number of elements is not limited to a specific number, but can be greater than or less than the specific number, unless otherwise specifically indicated, or in the case it is principally apparent that the number is limited to the specific number. Moreover, in the embodiments described below, it is needless to say that the constituent elements (including element steps) are not always essential, unless otherwise specifically indicated, or in the case where it is principally apparent that they are essential. Similarly, in the embodiments described below, when a reference is made to the shape or positional relationship of the constituent elements, a shape or positional relationship substantially analogous or similar to it is also embraced, unless otherwise specifically indicated, or in the case where it is utterly different in principle. This also applies to the above-described value and range. Further, in all of the drawings for describing the embodiments, elements having a like function will be identified by like reference numerals and overlapping description thereof will be omitted. Now, the embodiments of the present invention will hereafter be described specifically based on the accompanying drawings.

### Embodiment 1

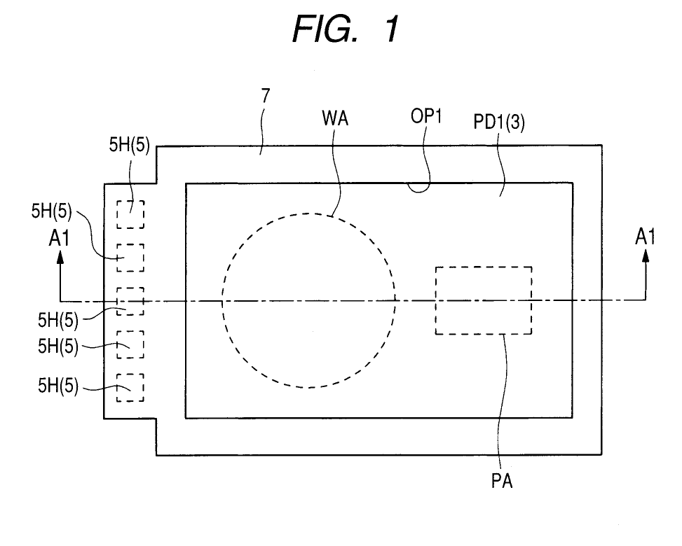

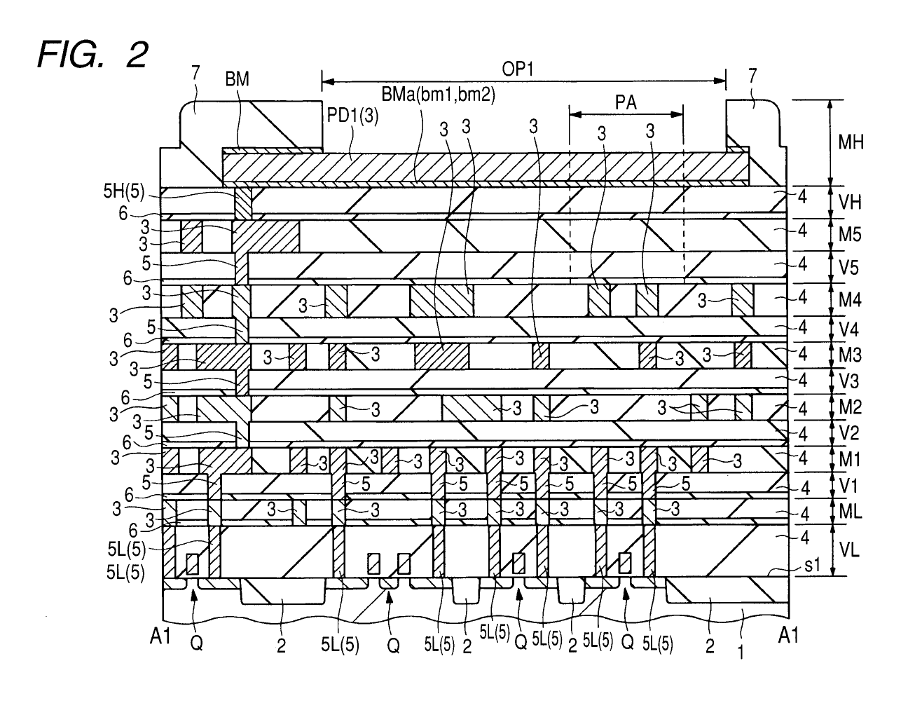

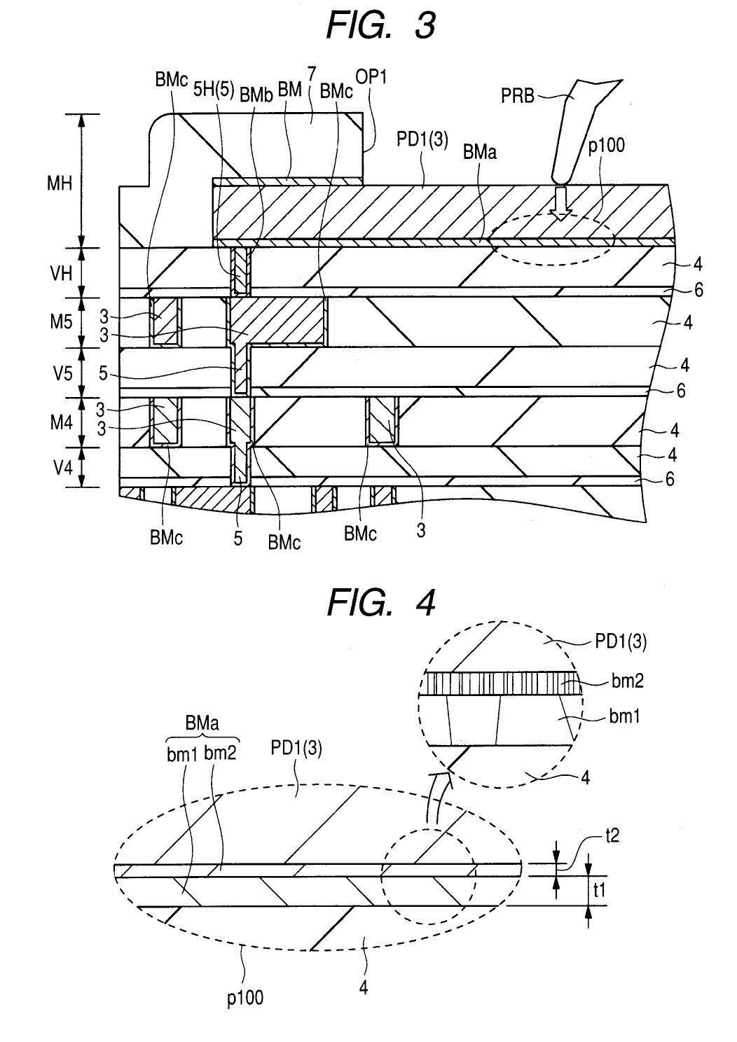

FIG. 1 is a plan view showing a principal part of a semiconductor device according to Embodiment 1. FIG. 2 is a cross-sectional view showing the principal part of the semiconductor device, illustrating a cross-section taken along line A1-A1 in the plan view of FIG. 1 and viewed in the direction of arrows. Of the semiconductor device according to Embodiment 1, these show a peripheral portion of a pad (an external terminal) PD1 to which probing for an electric property test and wire bonding are applied. Also, FIG. 3 is an enlarged cross-sectional view of a principal part of the peripheral portion of the pad PD1, and FIG. 4 is an enlarged cross-sectional view showing a principal part p100 of FIG. 3. With reference to FIGS. 1 to 4, a structure of the semiconductor device of Embodiment 1 will be explained in detail.

According to the semiconductor device of Embodiment 1, on a main surface s1 of a silicon substrate (semiconductor substrate) 1 of Embodiment 1, there is formed a semiconductor element comprising a field effect transistor (FET) Q having an MIS (Metal Insulator Semiconductor) structure. The field effect transistors Q are insulated, respectively, by a separator 2 having a shallow trench (ST) structure.

Further, covering the main surface s1 of the silicon substrate 1 including the field effect transistors Q, there are formed, in an alternately and repeatedly laminated manner, wiring layers ML, M1, M2, M3, M4, M5, MH, and connection layers VL, V1, V2, V3, V4, V5, VH. That is, the lowest connection layer VL is arranged directly over the main surface s1 of the silicon substrate 1. The lowest wiring layer ML is arranged over the connection layer VL. Then, over the wiring layer ML, there are arranged a first connection layer V1, a first wiring layer M1, a second connection layer V2, a second wiring layer M2, a third connection layer V3, a third wiring layer M3, a fourth connection layer V4, a fourth wiring layer M4, a fifth connection layer V5, and a fifth wiring layer M5, in this order. Finally, a top connection layer VH and a top wiring layer MH are arranged in this order.

Each of the wiring layers ML, M1 to M5, and MH has conductor patterns 3 of desired wiring forms and an interlayer insulating film 4 for insulation between the conductor patterns 3. Moreover, each of the connection layers VL, V1 to V5, and VH has via plugs (connection conductor pieces) 5 for connection between the conductor patterns 3 in the different wiring layers ML, M1 to M5, and MH, and an interlayer insulating film 4 for insulation between the via plugs 5. For example, the conductive pattern 3 of the third wiring layer M3 is electrically coupled with the conductive pattern 4 of the fourth wiring layer M4 by the via plug 5 of the fourth connection layer V4. In addition, the lowest connection layer ML serves to electrically couple the conductor pattern 3 of the lowest wiring layer ML with the field effect transistor Q. The connection conductor piece of the lowest connection layer ML is specifically called a “contact plug 5L.”

Moreover, the interlayer insulating film 4 comprises an insulating film including silicon oxide or a Low-k material as a principal component. The Low-k material is a material whose relative dielectric constant is lower than that of silicon oxide and it includes, for example, silicon oxide carbide (SiOC) etc. Even when the Low-k material is used as the interlayer insulating film 4, it is more preferable that, for interlayer insulating films 4 in the top connection layer VH, the fifth wiring layer M5, and the fifth connection layer V5, an insulating film (for example, a silicon oxide film) which is higher in mechanical strength than the Low-k material is used and that the Low-k material is used for interlayer insulating films 4 of other connection layers and wiring layers. As a result, destruction of the Low-k material by the stress of a package can be prevented. Moreover, a barrier insulating film 6 may be provided in a boundary portion between each of the wiring layers ML, M1 to M5, MH and each of the connection layers VL, V1 to V5, VH. The barrier insulating film 6 may comprise, for example, an insulating film including silicon carbonitride as a principal component.

In this regard, of the wiring layers ML, M1 to M5, and MH, the conductive pattern 3 of the top wiring layer MH is a pad PD1 to which an external bonding wire is coupled and a probe PRB for electric property test is contacted. In the top wiring layer MH, the pad PD1 is partially covered with a protective insulating film 7. The protective insulating film 7 is, for example, formed of a laminated structure comprising a silicon oxide film, a silicon nitride film deposited thereon, and a polyimide resin film further deposited thereon. In this regard, the protective insulating film 7 has an opening OP1 which allows part of the pad PD1 to be exposed. At the opening OP1, a part of the exposed portion of the pad PD1 has a wire contact area WA for wire bonding and a probe contact area PA for electric property test.

In this regard, the probe area PA represents a following area on the pad PD1 of the semiconductor device of Embodiment 1. That is, it is a portion on the pad PD1 which has, as marks indicating that the probe PRB has been brought into contact with the pad PD1, probe marks such as a dent or a raised portion of the pad PD1 itself. According to the investigation by the present inventors, the probe mark has a width of 10 μm or greater. Needless to say, the size of the probe mark does not exceed a size of the exposed portion (the opening OP1 of the protective insulating film 7) of the pad PD1.

The pad PD1 comprised of a conductor pattern 3 of the top wiring layer MH comprises a conductor including aluminum as a principal component. Further, a barrier conductor film BMa is arranged between the pad PD1 and the interlayer insulating film 4 of the top connection layer VH immediately below. A structure of the barrier conductor film BMa underlying the pad PD1 will be explained in detail with reference to another drawing. Moreover, in an interface with the protective insulating film 7 on an upper surface of the pad PD1, a barrier conductor film BM is formed.

According to the semiconductor device of Embodiment 1, the conductor patterns 3 of the wiring layers ML, and M1 to M5 other than the pad PD1 of the top wiring layer MH comprise conductors including copper as a main component.

Moreover, the contact plug 5L of the lowest connection layer VL which electrically couples the conductor pattern 3 of the lowest wiring layer ML with the field effect transistor Q formed on the main surface s1 of the silicon substrate 1 comprises a conductor including a high-melting-point metal as a principal component. An example of the metal having a high melting-point is tungsten. Furthermore, barrier conductor films are integrally arranged on a side face of the contact plug 5L of the lowest connection layer VL being a boundary with the interlayer insulating film 4 and on a bottom face thereof being a boundary with the field effect transistor Q. The barrier conductor film has a function to cause tungsten to grow and a function to enhance intimate contact between the wiring and the insulating film. Such a barrier conductor film includes, for example, titanium nitride.

Moreover, a top via plug (top connection conductor piece) 5H being a via plug 5 of the top connection layer VH which electrically couples the pad PD1 being the conductor pattern 3 of the top wiring layer MH with a conductor pattern 5 of the fifth wiring layer M5 being a wiring layer immediately below has the same structure as that of the contact plug 5L described above. That is, the top via plug 5H of the top connection layer VH comprises, for example, a conductor including tungsten as a principal component, and has a barrier conductor film BMb containing titanium nitride on a side face and a bottom face thereof.

According to the semiconductor device of Embodiment 1, via plugs 5 of the connection layers V1 to V5 other than the contact plug 5L of the lowest connection layer VL and the top via plug 5H of the top connection layer VH comprise conductors including copper as a principal component. The via plug 5 has, on its side face and bottom face, barrier conductor films BMc containing, for example, tantalum or tantalum nitride. In this regard, the conductor pattern 3 or the via plug 5 containing copper is formed by a so-called damascene (single damascene, dual damascene) method, wherein a hole (via hole, wiring hole, or both) is formed in the interlayer insulating film 4 and copper is embedded therein.

According to the semiconductor device of Embodiment 1, of the wiring layers ML, M1 to M5, and MH, in a wiring layer (namely, the fifth wiring layer M5) underlying the top wiring layer MH, the conductor pattern 3 is not formed in a portion overlapping, in a plane, with the probe contact area PA. In other words, the interlayer insulating film 4 alone is formed in the area concerned of the fifth wiring layer M5. With this arrangement, the following effects can be obtained.

When a conductor is arranged in a wiring layer below the probe contact area PA, the whole wiring layer tends to be plastically deformed by a pressure of probing. Due to its strain, a crack is easily generated in the interlayer insulating film 4. For example, in a case of the wiring layer having the conductor pattern 3 containing copper, when such a crack reaches the conductor pattern, copper can be oxidized. As a result, a short circuit or open of the conductor pattern 3 occurs, causing property deterioration.

On the other hand, according to the semiconductor device of Embodiment 1, as described above, in the fifth wiring layer M5 underlying the pad PD1 of the top wiring layer MH, the conductor pattern 3 is not arranged below the probe contact area PA. Accordingly, the plastic deformation during probing can be reduced, thereby suppressing the generation of a crack. Moreover, even when a crack occurs, by not arranging the conductor pattern 3 containing copper in the fifth wiring layer M5 below the probe contact area, property deterioration to be caused by oxidization of the probe contact area 3 etc. can be suppressed.

According to the semiconductor device of Embodiment 1, it is more preferable that, in upper and lower connection layers of the fifth wiring layer M5 underlying the top wiring layer MH (namely, the top connection layer VH and the fifth connection layer V5), in a portion overlapping with the probe contact area PA in a plane, the via plug 5 is not arranged. It is because, by not arranging the via plug 5 containing copper below the probe contact area PA of the connection layer close to the pad PD1, as in the case of the conductor pattern 3 of the above fifth wiring layer M5, the plastic deformation during probing can be reduced, and the generation of a crack can be suppressed. To summarize the above, according to the semiconductor device of Embodiment 1, in the top connection layer VH underlying the pad PD1 of the top wiring layer MH, the fifth wiring layer M5, and the fifth connection layer V5, it is more preferable not to arrange the conductor pattern 3 and the via plug 5 containing copper below the probe contact area PA.

As described above, by not arranging a copper wiring below the probe contact area PA over the pad PD1, it becomes possible to suppress occurrence of both the plastic deformation and the crack. According to the investigation by the present inventors, the above effect can be obtained by not arranging the conductor pattern 3 and the via plug 5 containing copper for 1 μm or more in a vertical direction below the probe contact area PA. That is, it is more preferable that, as described above, the fifth wiring layer M5 underlying the top wiring layers MH and the above layer, namely, the top connection layer VH and the lower layer, namely, the fifth connection layer V5 do not have the conductive pattern 3 and the via plug 5 below the probe contact area PA and, at the same time, the sum total of film thicknesses in the vertical direction is 1 μm or greater. The reason is that, when the interlayer insulating film 4 of 1 μm or more without a copper pattern is arranged below the probe contact area PA, even if copper in a lower layer is plastically deformed, the generation of a crack can be suppressed. In this regard, the vertical direction is a direction perpendicular to the main surface s1 of the silicon substrate 1, and is a film thickness direction of the wiring layers ML, M1 to M5, MH and connection layers VL, V1 to V5, VH. Moreover, according to the investigation by the present inventors, from the aspect of processing accuracy etc., it is desirable that the sum total of thicknesses of the top connection layer VH, the fifth wiring layer M5, and the fifth connection layer V5 is 3.5 μm or smaller. To summarize the above, in order to achieve the above effects, it is desirable that the sum total of the film thicknesses of the top connection layer VH not having the conductor pattern 3 and via plug 5, below the probe contact area PA, the fifth wiring layer M5, and the fifth connection layer V5 is 1 μm or greater but 3.5 μm or smaller.

As described above, of the pad PD1, below the probe contact area PA, the structure in which the conductor patterns are not arranged in the fifth wiring layer M5 etc. has been explained. According to the semiconductor device of Embodiment 1, below the portion of the pad PD1 exposed from the protective insulating film 7, it is more preferable that the conductor patterns 3 are not arranged in the fifth wiring layer M5 etc. That is, in the fifth wiring layer M5 underlying the top wiring layer MH, in a portion overlapping with the opening OP1 of the protective insulating film 7 in a plane, the conductor pattern 3 is not provided. It is because, as described above, in the fifth wiring layer M5 close to the pad PD1, by not arranging the conductor pattern 3 containing copper, occurrence of plastic deformation can be further suppressed. As a result, the generating of a crack in the interlayer insulating film 4 can be suppressed. Because of the same reason, it is more preferable that the via plugs 5 are not arranged in the areas concerned in the upper layer of the fifth wiring layer M5, namely, the top connection layer VH and the lower layer of the fifth wiring layer M5, namely, the fifth connection layer V5.

Further, at a bottom of the pad PD1, being a barrier conductor film BMa arranged in an interface with the top connection layer VH, the semiconductor device of Embodiment 1 has a structure as follows. That is, the barrier conductor film BMa arranged at the bottom of the pad PD1 comprised of a laminated film of a first barrier conductor film bm1 comprising a conductor including titanium as a principal component and a second barrier conductor film bm2 comprising a conductor including titanium nitride as a principal component. In particular, the first barrier conductor film bm1 is arranged below the second barrier conductor film bm2. In other words, the first barrier conductor film bm1 is arranged on a side in contact with the interlayer insulating film 4 of the top connection layer VH and the second barrier conductor film bm2 is arranged on a side in contact with the pad PD1.

Further, in the barrier conductor film BMa below the pad PD1 of the semiconductor device according to Embodiment 1, regarding film thicknesses in a vertical direction, a film thickness t1 of the first barrier conductor film bm1 containing titanium is greater than a film thickness t2 of the second barrier conductor film bm2 containing titanium nitride. Conventionally, as the barrier conductor film of a pad containing aluminum, in order to prevent a reaction with a metal (in this case, tungsten of the top via plug 5H) contacting in the lower layer, a barrier conductor film including thick titanium nitride as a principal component is chosen. Further, in order to ensure intimate contact and electric connection between the titanium nitride and the lower layer metal, thin titanium is formed in between.

On the other hand, according to the semiconductor device of Embodiment 1, titanium is mainly formed thickly. Then, titanium nitride is formed thereon to produce a barrier conductor film BMa, which is arranged below the pad PD1. The reason will be explained in detail later.

According to the semiconductor device of Embodiment 1, by allowing the barrier conductor film BMa arranged below the pad PD1 to have the above structure, the following effects can be obtained. That is, during an electric property test performed by bringing the probe PRB into contact with the probe contact area PA of the pad PD1, the generation of a crack is suppressed in an interlayer insulating film 4 below the pad PD1. The reason is as follows.

According to the investigation by the present inventors, it was found that when titanium and titanium nitride were compared, titanium nitride had smaller crystal grains, being comprised of columnar crystals. On the other hand, titanium had larger crystal grains, being not comprised of columnar crystals (hereafter, called “granular crystals”). More specifically, it was found that, as shown in FIG. 4, titanium nitride as the second barrier conductor film bm2 was formed such that columns rise along a film thickness direction. Therefore, it was found that a crack was liable to occur through a grain boundary by a pressure in a vertical direction at the time of probing. On the other hand, it was found that titanium as the first barrier conductor film bm1 was comprised of granular crystals having few grain boundaries in the film thickness direction. Also, with respect to a pressure in the vertical direction at the time of probing, a crack is less likely to occur. From this aspect, as the barrier conductive film BMa, the thicker the first barrier conductor film bm1 containing titanium is made, the better the crack preventive property during probing can be. However, in order to suppress a reaction between titanium (the first barrier conductor film bm1) and aluminum (pad PD1), it is more preferable to arrange titanium nitride (the second barrier conductor film bm2) in between. In this case, because of the above reason, the greater the film thickness of the titanium nitride is, the poorer the crack preventive property during probing becomes.

Therefore, in the semiconductor device of Embodiment 1, it becomes possible to suppress the generation of a crack by using, as a main component of the barrier conductor film BMa underlying the pad PD1 to which probing is applied, a first barrier conductor film bm1 containing titanium having larger crystal grains in the form of granular crystals. In other word, according to the semiconductor device of Embodiment 1, the generation of a crack is suppressed by mainly using the first barrier conductive film bm1 containing titanium in the form of granular crystals rather than by using the second barrier conductor film bm2 containing titanium nitride in the form of columnar crystals. In addition, as described above, according to the semiconductor device of Embodiment 1, in order to suppress the reaction between titanium and aluminum, the second barrier conductor film bm2 containing titanium nitride is arranged between the first barrier conductor film bm1 containing titanium and the pad PD1 containing aluminum.

As described above, according to the semiconductor device of Embodiment 1, in the barrier conductor film BMa below the pad PD1, there is provided mainly the first barrier conductor film bm1 containing titanium in the form of granular crystals rather than the second barrier conductor film bm2 containing titanium nitride in the form of columnar crystals, being liable to have cracks. As a result, even when a stress is applied during the probing of the pad PD1, it becomes possible to achieve a structure in which a crack is not generated easily in the interlayer insulating film 4 etc. in the lower layer. Furthermore, according to the semiconductor device of Embodiment 1, as described above, the conductor patterns 3 containing copper are not arranged in the fifth wiring layer M5 etc. below the probe contact area PA. Thus, there is provided a structure in which plastic deformation is not easily caused by a pressure during the probing, suppressing the generation of a crack. Furthermore, with this structure, even if a crack occurs, it does not easily reach the conductor pattern 3, which suppresses occurrence of a short circuit or open of the wiring. Thus, according to the semiconductor device of Embodiment 1, the probe resistance property can be improved.

According to the further investigation by the present inventors, in the barrier conductor film BMa of the semiconductor device of Embodiment 1, it was found that the above effects become more prominent by allowing a film thickness t1 of the first barrier conductor film bm1 containing titanium whose crystal grain is large and is less likely to have a crack to be at least twice as great as a film thickness t2 of the second barrier conductor film bm2 containing titanium nitride which is in the form of columnar crystals and is likely to have a crack. Furthermore, it was found that the above effect became more prominent by allowing the film thickness t1 of the first barrier conductor film bm1 containing titanium to be 20 nm or greater. In this regard, in order to suppress a reaction between the first conductor film bm1 containing titanium and the pad PD1 containing aluminum, it is desirable that the film thickness of the second conductor film bm2 containing titanium nitride is 5 nm or greater. Further, it is more preferable that the sum total of the thicknesses of the first barrier conductor film bm1 and the second barrier conductor film bm2 in a vertical direction (namely, a film thickness of the barrier conductor film BMa) is 200 nm or smaller. This is because a main component of the pad PD1 is aluminum of low resistance, the barrier conductor film BMa introduced from the aspects of intimate-contact property and reaction suppression has a resistance higher than that of aluminum, and it is preferable that the barrier conductor film BMa is not too thick.

Moreover, as described earlier, the field effect transistors Q are formed, as semiconductor elements, on a main surface s1 of the silicon substrate 1. According to the semiconductor device of Embodiment 1, particularly, even on the main surface s1 of the silicon substrate at a position overlapping with the pad PD1 in a plane, it is more preferable that the field effect transistors Q are formed as the semiconductor elements. The reason is that, by arranging the field effect transistors Q also in the area below the pad PD1, a space on a surface of the silicon substrate 1 can be used effectively, improving the degree of integration.

In this regard, a crack is liable to occur, during probing, particularly in the lower portion of the probe contact area PA of the lower portion of the pad PD1. Therefore, the semiconductor element should not be arranged on the silicon substrate 1 of the area concerned if possible. However, according to the semiconductor device of Embodiment 1, as described above, the generation of a crack below the probe contact area PA can be suppressed. Therefore, even if the semiconductor element is arranged below the pad PD1, the above problem is less likely to arise. Thus, the semiconductor device of Embodiment 1 can be further effectively applied to a structure in which the field effect transistors Q are arranged even on the silicon substrate 1 below the pad PD1.

Moreover, according to the semiconductor device of Embodiment 1, in a conductor pattern 3 arranged in a second lower-layer wiring layer (namely, a fourth wiring layer M4) from the top wiring layer MH having the pad PD1, it is more preferable that, in an area overlapping with the probe contact area PA in a plane, a conductor pattern 3 whose wiring width is 2 μm or smaller is arranged. In other words, regarding the fourth wiring layer M4, it is more preferable that a wiring width of the conductor pattern 3 arranged below the probe contact area PA is 2 μm or smaller. The reason will be explained below.

The fourth wiring layer M4 is disposed farther from the pad PD1 than the fifth wiring layer M5. Therefore, it is less likely to be plastically deformed than the fifth wiring layer M5. Even so, if a needle pressure of the probe PRB is high, the fourth wiring layer M4 is plastically deformed and can have a crack in the interlayer insulating film 4. Therefore, as described above, in regard to the fourth wiring layer M4, the width of the conductor pattern 3 arranged immediately below the probe contact area PA of the pad PD1 is limited to 2 μm or smaller. In this way, the plastic deformation is further suppressed, and it becomes possible to bring the probe PRB into contact with the pad PD1 at a higher needle pressure, further stabilizing the probe inspection.

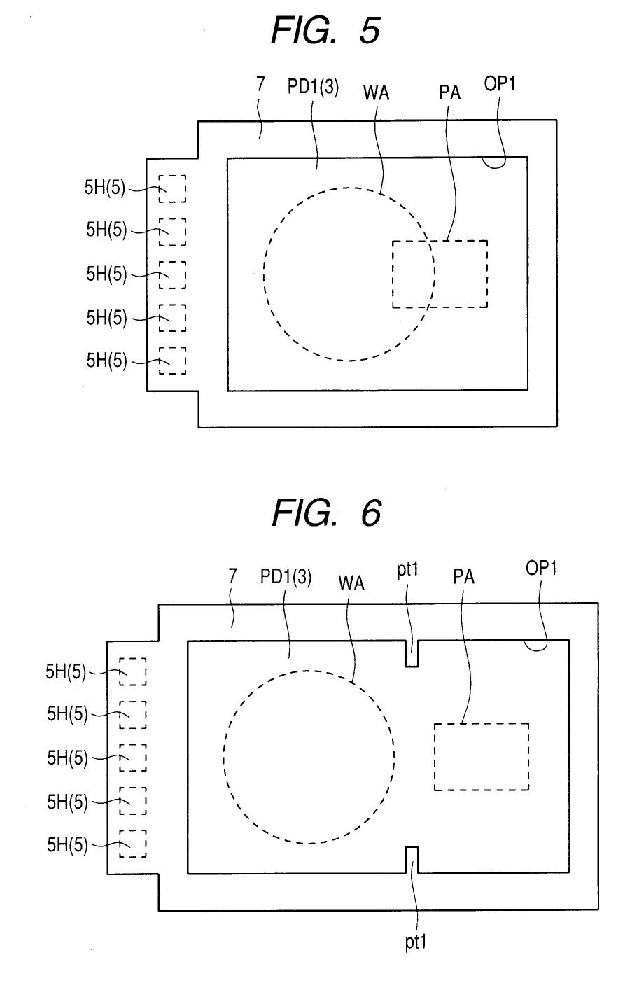

Also, the shape in a plane of the pad PD1 of the semiconductor device of Embodiment 1 is not limited to the one shown in FIG. 1, and it may be one of those shown in plan views of principal parts of FIGS. 5 and 6.

FIG. 5 is a plan view showing the principal part of the pad PD1 in which the wire contact area WA and the probe contact area PA are partially overlapped. With such a structure, an area of the plane occupied by the pad PD1 can be reduced and a higher performance of the semiconductor device by higher integration can be achieved. To such a semiconductor device also, a technology of the semiconductor device of Embodiment 1 described above can be similarly applied effectively.

FIG. 6 is a plan view showing the principal part of the pad PD1 having, in a plane, in the protective insulating film 7 covering the pad PD1, a protruding part pt1 as a mark for a boundary between the two areas so that the wire contact area WA and the probe contact area PA can be distinguished visually. With this structure, it is possible to design the probe contact area PA for carrying out probing at the time of probe inspection and the wire connection area WA for connecting a bonding wire without having them interfere with each other. For example, if the bonding wire is connected to a surface of the pad PD1 made rough by probing, the states of intimate contact and connection are deteriorated. However, with the above structure in which the probe contact area PA is less likely to overlap with the wire connection area WA, the property of the semiconductor device can be improved.

### Embodiment 2

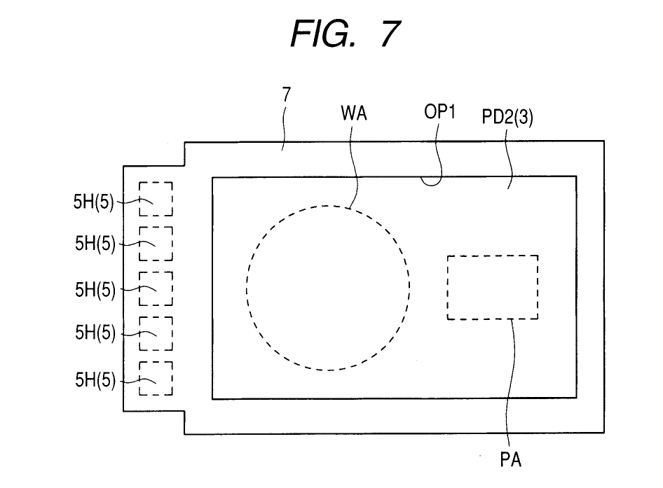

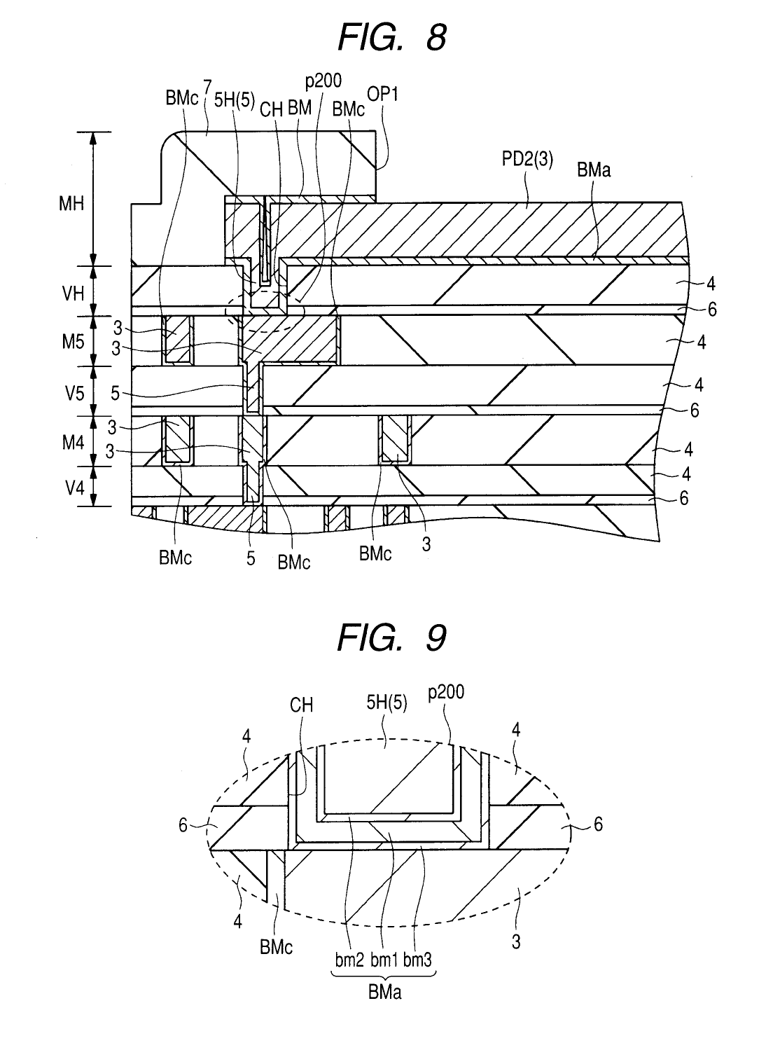

Now, with reference to FIGS. 7 to 9, a semiconductor device of Embodiment 2 will be explained. FIG. 7 is a plan view showing a principal part of the semiconductor device according to Embodiment 2. FIG. 7 shows, of the semiconductor device of Embodiment 2, a peripheral portion of a pad (external terminal) PD2 for carrying out probing of the electric property test and wire bonding. FIG. 8 is an enlarged cross-sectional view showing the peripheral portion of the pad PD2, and FIG. 9 is an enlarged cross-sectional view showing a principal part p200 of FIG. 8. With reference to FIGS. 7 to 9, a structure of the semiconductor device of Embodiment 2 will be explained in detail.

Except for the following points, the semiconductor device of Embodiment 2 has basically the same structure as in the semiconductor device of Embodiment 1 and the effects obtained thereby.

According to the semiconductor device of Embodiment 2, the top via plug (top connection conductor piece) 5H being the via plug 5 of the top connection layer VH for electrically coupling the pad PD2 of the top wiring layer MH with the conductor pattern 3 of the fifth wiring layer M5 underlying the top wiring layer MH has the following structure. That is, according to the semiconductor device of Embodiment 2, the top via plug 5H is formed so as to embed a connection hole CH (contact hole, or via hole) with the same material as that of the barrier conductor film BMa of the top wiring layer MH and the pad PD2. In this regard, the connection hole CH is the one which passes the interlayer insulating film 4 of the top connection layer VH from an upper surface in contact with the pad PD2 to an undersurface in contact with the conductor pattern 3.

According to a step of manufacturing the semiconductor device of Embodiment 2, by embedding the upper surface of the top connection layer VH including the connection hole CH described above, the barrier conductor film BMa and the pad PD2 (conductor pattern 3) are formed in this order. Then, patterning is performed by a lithography method etc. to form the pad PD2 comprising a conductor pattern 3 of a desired shape.

For example, when forming aluminum as the pad PD2 by sputtering etc., in order to fully embed the inside of the connection hole CH, it is necessary to set a diameter of the connection hole CH to be comparatively large. For example, as in the top via plug 5H of the semiconductor device according to Embodiment 1, being compared to the case where tungsten formed by the damascene method is applied, the diameter of the connection hole CH is larger in the case where, as in the top via plug 5H of the semiconductor of Embodiment 2, aluminum formed by sputtering is applied.

On the other hand, according to the semiconductor device of Embodiment 2, as described above, the top via plug 5H of the top connection layer VH and the pad PD2 of the top wiring layer MH can be formed collectively, simplifying the manufacturing process. Simplification of the manufacturing process reduces a manufacturing cost, thereby improving the production yield.

In the case of the top via plug 5H of Embodiment 2, the barrier conductor film BMa of a lower portion of the pad PD2 is also integrally arranged on a wall face of the connection hole CH of the top connection layer VH. That is, at the bottom of the connection hole CH, the barrier conductor film BMa is in contact with the conductor pattern 3 of the fifth wiring layer M5. In this regard, as explained in the case of the semiconductor device of Embodiment 1, the barrier conductor film BMa is comprised of a laminated layer film comprising, from below, a first barrier conductor film bm1 containing titanium; and a second barrier conductor film bm2 containing titanium nitride. Therefore, in this state, the first barrier conductor film bm1 containing titanium comes into contact with the conductor pattern 3 containing copper. However, it is known that titanium reacts with copper, which increases electric resistance at the contact portion.

Accordingly, the barrier conductor film BMa of the semiconductor device of Embodiment 2 has, in a further lower layer of the first barrier conductor film bm1, a third barrier conductor film bm3 comprising a conductor including titanium nitride as a principal component. As described above, the barrier conductor film BMa of Embodiment 2 is integrally formed covering from below the pad PD2 to the inside of the connection hole CH of the top connection layer VH. Therefore, by arranging the third barrier conductor film bm3 described above, at the bottom of the connection hole CH, the third barrier conductor film bm3 containing titanium nitride prevents the first barrier conductor film 1 containing titanium from coming into contact with the third conductor pattern containing copper. Thus, the reaction between titanium and copper can be suppressed.

As explained with reference to FIGS. 1 to 4, in the semiconductor device of Embodiment 1, with respect to a pressure during the probe inspection, the barrier conductor film BMa has the effect of suppressing the generation of a crack. In the semiconductor device of Embodiment 2 also, the barrier conductor film BMa underlying the pad PD2 has the third barrier conductor film bm3 containing titanium nitride in the form of columnar crystals. When its film thickness is smaller than that of the first barrier conductor film bm1 containing titanium, a similar effect can be made apparent.

Further, below the probe contact area PA of a pad PD4, it is more preferable that the thickness of the first barrier conductor film bm1 is at least twice as great as that of the third barrier conductor film bm3. At the same time, it is more preferable that the thickness of the third barrier conductor film bm3 is 5 nm or greater. The reason is the same as the one for setting the film thickness condition of the first barrier conductor film bm1 with respect to the second barrier conductor film bm2 in Embodiment 1. Moreover, other film thickness conditions are the same as in Embodiment 1, and overlapping descriptions thereof will be omitted. According to the semiconductor device of Embodiment 2, the sum total of film thicknesses of the first barrier conductor film bm1, the second barrier conductor film bm2, and the third barrier conductor film bm3 is 200 nm or smaller. Such a film thickness condition can make the effect for improving probe resistance apparent. Therefore, it is satisfactory as long as the condition is at least applied to the barrier conductor film BMa below the probe contact area PA of the pad PD4.

With the above structure of the semiconductor device of Embodiment 2, the generation of a crack is suppressed during the probing, improving the production yield.

### Embodiment 3

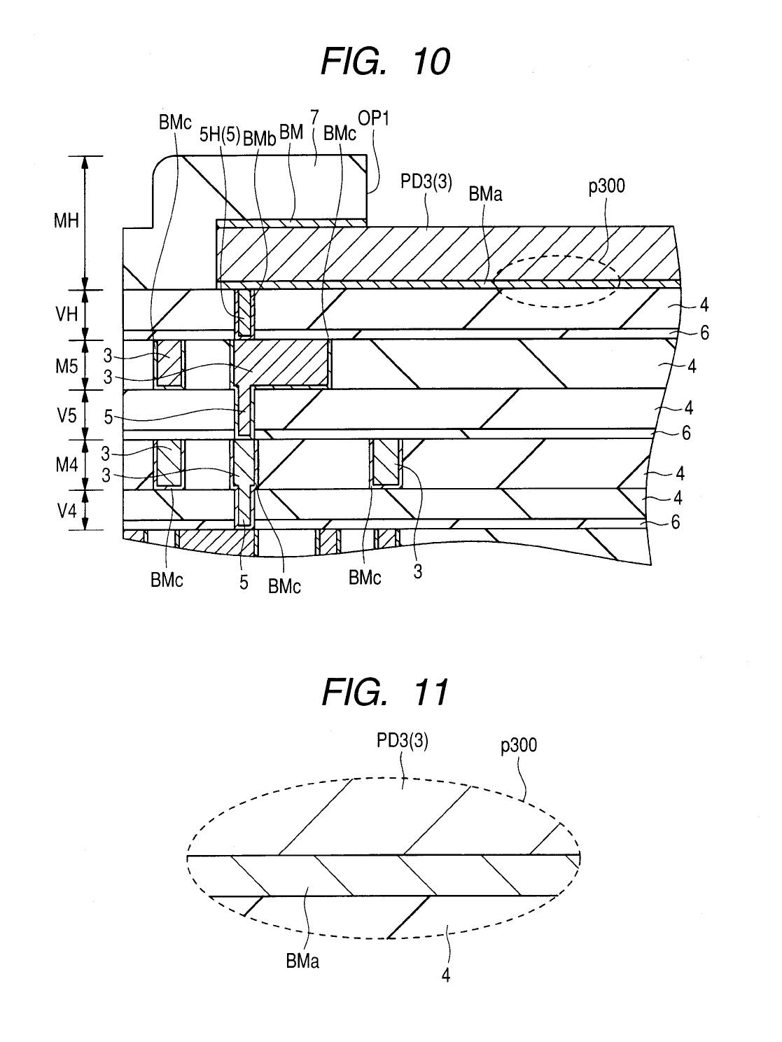

With reference to FIGS. 10 and 11, a semiconductor device of Embodiment 3 will be explained. FIG. 10 is a cross-sectional view showing a principal part of the semiconductor device and corresponds to FIG. 3 of the semiconductor device of Embodiment 1. FIG. 11 is an enlarged cross-sectional view of a principal part p300 of FIG. 10. Except for the following points, the semiconductor device of Embodiment 3 has the same structure as in Embodiments 1 and 2, and the effects obtained thereby.

According to the semiconductor device of Embodiment 3, a barrier conductor film BMa arranged between a pad PD3 of the top wiring layer MH and the interlayer insulating film 4 of the top connection layer VH immediately below comprises a conductor including tantalum or tantalum nitride as a principal component.

Tantalum or tantalum nitride has large crystal grains and has, as described above, a probe resistance like titanium having a high probe resistance. In this regard, according to the semiconductor device of Embodiment 1, the barrier conductor film BMa is formed by laminating titanium (first barrier conductor film bm1) for improving the probe resistance and titanium nitride (second barrier conductor film bm2) for suppressing a reaction with the pad PD1. On the other hand, tantalum or tantalum nitride of the semiconductor device of Embodiment 3 has a low reactivity with the pad PD3 containing aluminum. Therefore, it is not necessary to provide a conductor layer for suppressing reaction. As a result, the effect of improvement in the probe resistance similar to the one in Embodiment 1 can be achieved by the barrier conductor film BMa having a simpler structure. This can reduce the manufacturing cost and improve the production yield.

According to the further investigation by the present inventors, the barrier conductor film BMa comprising a conductor including tantalum nitride as a principal component is in a non-crystalline (amorphous) state. It was found that, since there was no grain field in the non-crystalline state, a crack was further less likely to be generated by a stress. It was found that the above effect became more prominent when the film thickness of tantalum nitride was 20 nm or greater. Because of this reason, according to the semiconductor device of Embodiment 3, it is more preferable that the film thickness of the barrier conductor film BMa comprising a conductor film including tantalum or tantalum nitride as a principal component is 20 nm or greater. In addition, because of the reason similar to the one described in Embodiment 1, it is more preferable that the film thickness of the barrier conductor film BMa is 200 nm or smaller.

### Embodiment 4

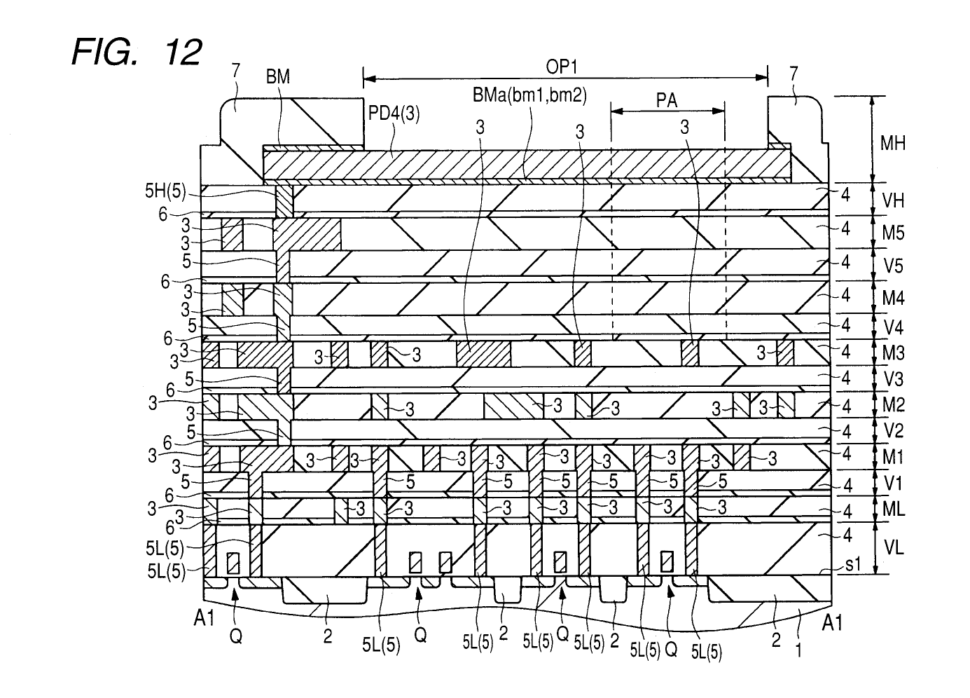

With reference to FIG. 12, a semiconductor device of Embodiment 4 will be explained. FIG. 12 is a cross-sectional view showing a principal part of the semiconductor device and corresponds to FIG. 2 of the semiconductor device of Embodiment 1. Except for the following points, the semiconductor device of Embodiment 4 has the same structure as that of the semiconductor of Embodiment 1, 2, or 3, and the effects obtained thereby.

According to the semiconductor device of Embodiment 4, of the wiring layers ML, M1 to M5, and MH, in a portion overlapping with the probe contact area PA of the pad PD4 in a plane in the wiring layer (namely, the fifth wiring layer M5) underlying the top wiring layers MH and in the second lower-layer wiring layer (namely, the fourth wiring layer M4), a conductive pattern 3 is not formed. In other words, in the areas concerned of the fifth wiring layer M5 and the fourth wiring layer M4, interlayer insulating films 4 alone are formed. With this structure, the following effects can be obtained.

As explained earlier with respect to the semiconductor device of Embodiment 1, by not providing the conductor pattern 3 below the probe contact area PA of the pad PD1, plastic deformation is suppressed, and a probe resistance property is improved. In Embodiment 1, the effectiveness of the structure in which the conductor pattern 3 is not formed in the area concerned of the fifth wiring layer M5 immediately below the pad PD1 was explained. From the same aspect, according to the semiconductor device of Embodiment 4, the conductor pattern 3 is not arranged in the area concerned of the fourth wiring layer M4 still below, further suppressing the plastic deformation. As a result, with the structure of the semiconductor device of Embodiment 4, the probe resistance can be further improved.

### Embodiment 5

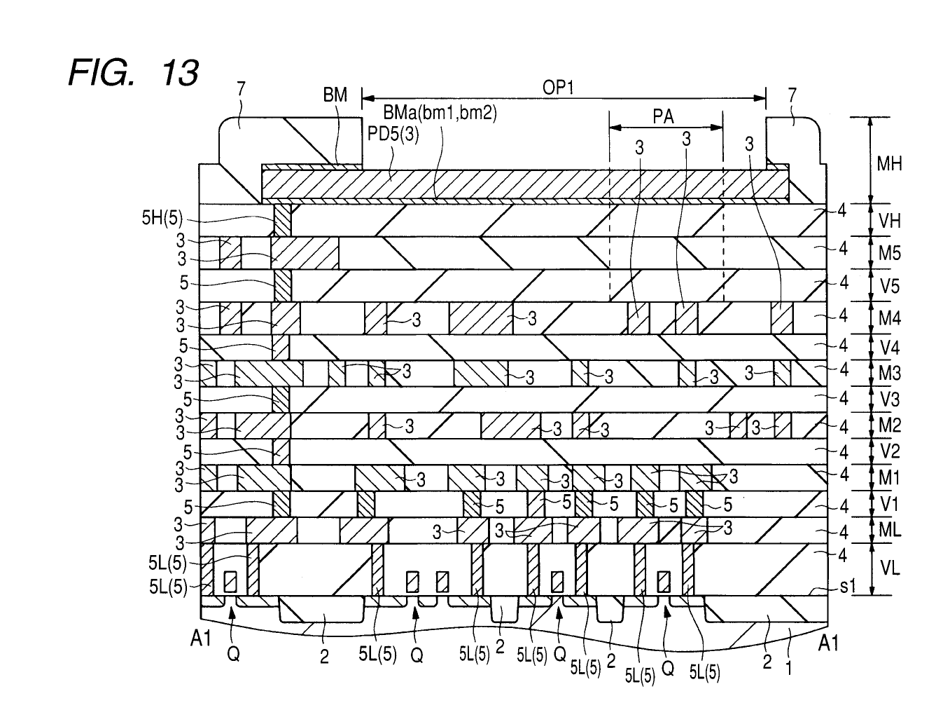

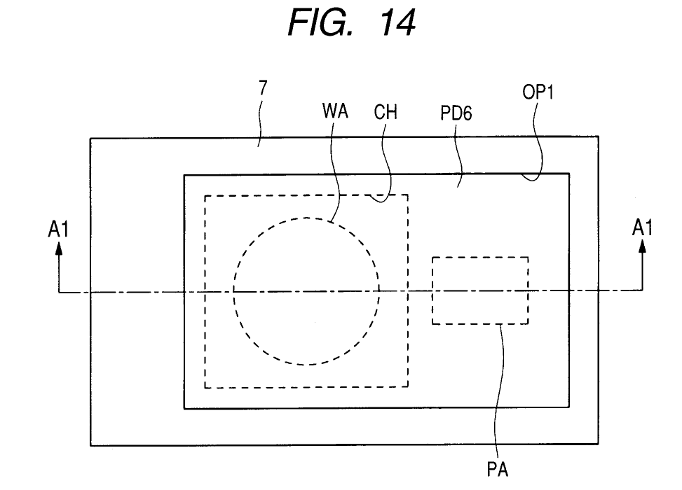

With reference to FIG. 13, a semiconductor device of Embodiment 5 will be explained. FIG. 13 is a cross-sectional view showing a principal part of the semiconductor device and corresponds to FIG. 2 of the semiconductor device of Embodiment 1. Except for the following points, the semiconductor device of Embodiment 5 has the same structure as that of the semiconductor device of Embodiment 1, 2, 3, or 4, and the effects obtained thereby.

According to the semiconductor device of Embodiment 5, the conductor pattern 3 that each of the wiring layers ML, M1 to M5, and MH has is formed by a conductor including aluminum as a principal component. As compared to copper, aluminum is lower in mechanical strength. Therefore, when probing is applied to a pad PD5 etc., plastic deformation is likely to occur because of its stress. Also, in the semiconductor device having such aluminum as a conductor pattern, a crack is likely to occur. From this aspect, to the semiconductor device of Embodiment 5 having aluminum as the conductor pattern 3, the structure of the semiconductor device of Embodiment 1, 2, 3, or 4 capable of improving probe resistance can be more effectively applied.

### Embodiment 6

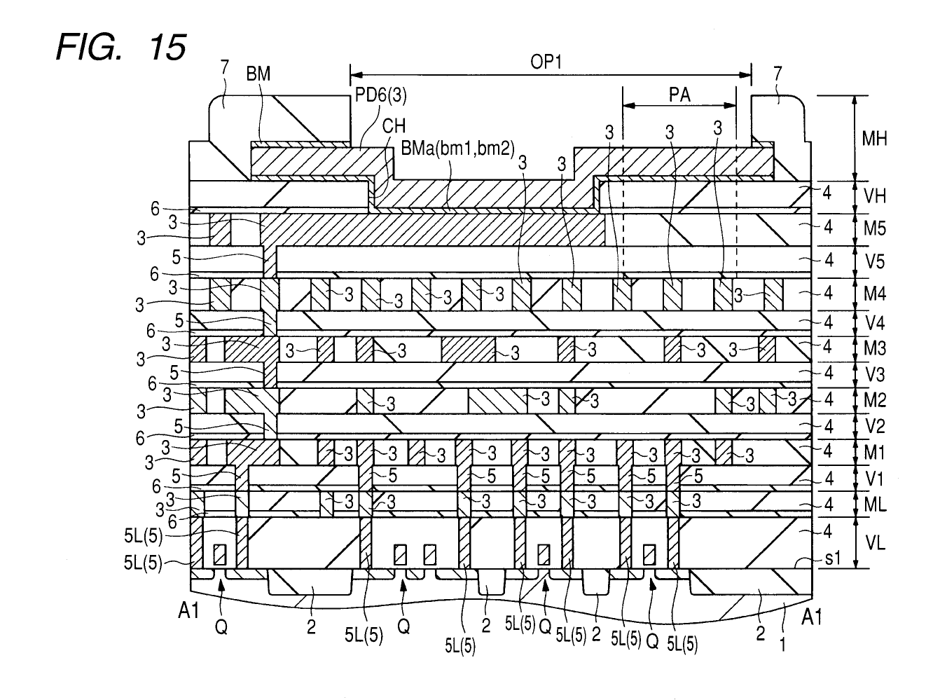

With reference to FIGS. 14 and 15, a semiconductor device of Embodiment 6 will be explained. FIG. 14 is a plan view showing a principal part of the semiconductor device of Embodiment 6. Of the semiconductor device according to Embodiment 6, FIG. 14 shows a peripheral portion of a pad PD6 to which probing during an electric property test or wire bonding is applied. FIG. 15 is an enlarged cross-sectional view showing the principal part of the peripheral portion of the pad PD6. With reference to FIGS. 14 and 15, the structure of the semiconductor device of Embodiment 6 will be explained in detail. Except for the following points, the semiconductor device of Embodiment 6 has the same structure as that of the semiconductor device of Embodiment 1, 2, 3, 4, or 5, and the effects obtained thereby.

The semiconductor device of Embodiment 6 has the following structure as an electric continuity mechanism between the pad PD6 of the top wiring layer MH and the conductor pattern 3 of the fifth wiring layer M5 immediately below. That is, as in the semiconductor device of Embodiment 2, according to the semiconductor device of Embodiment 6, the material same as those of the barrier conductor film BMa and the pad PD6 is integrally formed by being embedded in a connection hole CH formed in the top connection layer VH. However, as a point being different from the semiconductor device of Embodiment 2, according to the semiconductor device of Embodiment 6, as viewed in a plane, the connection hole CH lies in an opening OP1 of a protective insulating film 7 allowing the pad PD6 to be exposed, and is wider than the connection hole CH of Embodiment 2. Further, in the fifth wiring layer M5, the conductor pattern 3 is arranged so as to be in contact with a bottom portion of the connection hole CH.

However, the conductor pattern 3 of the fifth wiring layer M5 is not arranged below the probe contact area PA of the pad PD6, which is the same as the cases of Embodiments 1 to 5. Accordingly, it becomes possible to improve probe resistance by applying the present invention to the semiconductor device having the structure of Embodiment 6.

Although the invention made by the present inventors has been described above concretely by way of embodiments thereof, it goes without saying that the invention is not limited to the above embodiments and that various changes may be made within the scope not departing from the gist of the invention.

What is claimed is:

1. A semiconductor device comprising:
wiring layers and connection layers alternately and repeatedly laminated so as to cover a main surface of a semiconductor substrate,
wherein each of the wiring layers has conductor patterns and an interlayer insulating film for insulation between the conductor patterns,
wherein each of the connection layers has a connection conductor piece for coupling the conductor patterns in the different wiring layers, and the interlayer insulating film for insulation between the connection conductor pieces,
wherein a top wiring layer of the wiring layers includes an external terminal formed by the conductor pattern and a protective insulating film covering the external terminal,
wherein the external terminal comprises a conductor including aluminum as a principal component,
wherein the protective insulating film has an opening for allowing part of the external terminal to be exposed,
wherein the external terminal has a probe contact area in apart of the area exposed from the opening of the protective insulating film,
wherein the conductor pattern is not arranged in a portion overlapping with the probe contact area in a plane in a wiring layer which is one layer lower than the top wiring layer of the wiring layers,
wherein a barrier conductor film is arranged between the external terminal and the underlying interlayer insulating film,
wherein the barrier conductor film comprises a laminated film of a first barrier conductor film including titanium as a principal component and a second barrier conductor film including titanium nitride as a principal component,
wherein the first barrier conductor film is arranged on a side in contact with the interlayer insulating film, and the second barrier conductor film is arranged on a side in contact with the external terminal, respectively, and
wherein a thickness of the first barrier conductor film in a vertical direction is greater than that of the second barrier conductor film.

2. A semiconductor device according to claim 1, wherein the thickness of the first barrier conductor film in the vertical direction is at least twice as great as the thickness of the second barrier conductor film in the vertical direction.

3. A semiconductor device according to claim 2,
wherein the thickness of the first barrier conductor film in the vertical direction is 20 nm or greater,
wherein the thickness of the second barrier conductor film in the vertical direction is 5 nm or greater, and
wherein the sum total of the thicknesses of the first barrier conductor film and the second barrier conductor film in the vertical direction is 200 nm or smaller.

4. A semiconductor device according to claim 3, wherein a semiconductor element is formed over a main surface of the semiconductor substrate at a position overlapping with the external terminal in a plane.

5. A semiconductor device according to claim 4, wherein the connection conductor piece is not provided, in a portion overlapping with the probe contact area in a plane, in each of the upper and lower connection layers of the wiring layer which is one layer lower than the top wiring layer.

6. A semiconductor device according to claim 5,
wherein the conductor pattern is not arranged in a portion overlapping with the opening of the protective insulating film in a plane in a wiring layer which is one layer lower than the top wiring layer of the wiring layers, and
wherein the connection conductor piece is not arranged, in a portion overlapping with the opening of the protective insulating film in a plane, in each of the upper and lower connection layers of the wiring layer which is one layer lower than the top wiring layer.

7. A semiconductor device according to claim 6, wherein the sum total of thicknesses of the wiring layer which is one layer lower than the top wiring layer and the upper and lower connection layers in a vertical direction is 1 μm or greater but 3.5 μm or smaller.

8. A semiconductor device according to claim 7, wherein, over a portion of the external terminal exposed from the opening of the protective insulating film, the probe contact area has a probe mark having a width of 10 μm or greater.

9. A semiconductor device according to claim 8, wherein a top connection conductor piece for coupling the external terminal of the top wiring layer with the conductor pattern of the wiring layer which is one layer lower than the top wiring layer contains the same material as those of the barrier conductor film of the top wiring layer and the external terminal and is formed so as to integrally embed a connection hole.

10. A semiconductor device according to claim 9, wherein the first barrier conductor film is of granular crystals and the second barrier conductor film is of columnar crystals.

11. A semiconductor device according to claim 10,
wherein the conductor pattern included in each of the wiring layers other than the top wiring layer comprises a conductor including copper as a principal component,
wherein the barrier conductor film in the top connection conductor piece further has a third barrier conductor film including titanium nitride as a principal component in a portion in contact with the conductor pattern of the wiring layer,
wherein the third barrier conductor film separates the wiring layer from the first barrier conductor film so that they may not be in contact with each other,
wherein a thickness of the first barrier conductor film in a vertical direction is at least twice as great as a thickness of the third barrier conductor film in a vertical direction,
wherein the thickness of the third barrier conductor film in the vertical direction is 5 nm or greater, and
wherein the sum total of the thicknesses of the first barrier conductor film, the second barrier conductor film, and the third barrier conductor film is 200 nm or smaller.

12. A semiconductor device according to claim 10, wherein the conductor pattern included in the wiring layer comprises a conductor including aluminum as a principal component.

13. A semiconductor device comprising:
wiring layers and connection layers alternately and repeatedly laminated so as to cover a main surface of a semiconductor substrate,
wherein each of the wiring layers has conductor patterns and an interlayer insulating film for insulation between the conductor patterns,
wherein each of the connection layers has a connection conductor piece for coupling the conductor patterns in the different wiring layers and the interlayer insulating film for insulation between the connection conductor pieces,
wherein a top wiring layer of the wiring layers has an external terminal formed by the conductor pattern and a protective insulating film covering the external terminal,
wherein the external terminal comprises a conductor including aluminum as a principal component,
wherein the protective insulating film has an opening for allowing part of the external terminal to be exposed,
wherein the external terminal has a probe contact area in a part of the area exposed from the opening of the protective insulating film,
wherein the conductor pattern is not arranged in a portion overlapping with the probe contact area in a plane in a wiring layer which is one layer lower than the top wiring layer of the wiring layers,
wherein a barrier conductor film is arranged between the external terminal and the underlying interlayer insulating film,
wherein a top connection conductor piece being the connection conductor piece for coupling the external terminal of the top wiring layer with the conductor pattern of the wiring layer which is one layer lower than the top wiring layer contains the same material as those of the barrier conductor film of the top wiring layer and the external terminal and is formed so as to integrally embed a connection hole,
wherein the conductor pattern included in each of the wiring layers other than the top wiring layer has a conductor including copper as a principal component,
wherein the barrier conductor film comprises a laminated film of a first barrier conductor film including titanium as a principal component and second and third barrier conductor films including titanium nitride as a principal component, and
wherein the first barrier conductor film is arranged so as to be sandwiched between the second barrier conductor film and third barrier conductor film.

14. A semiconductor device according to claim 13, wherein, of the barrier conductor films, a film thickness of the first barrier conductor film in a vertical direction is greater than that of the second barrier conductor film and the third barrier conductor film.

15. A semiconductor device according to claim 14,
wherein the thickness of the first barrier conductor film in the vertical direction is 20 nm or greater,
wherein each of the thicknesses of the second and third barrier conductor films in the vertical direction is 5 nm or greater, and
wherein the sum total of the film thicknesses of the first barrier conductor film, the second barrier conductor film, and the third barrier conductor film is 200 nm or smaller.

16. A semiconductor device comprising:
a semiconductor element formed over a main surface of a semiconductor substrate; and
wiring layers and connection layers alternately and repeatedly laminated so as to cover the main surface of the semiconductor substrate,
wherein each of the wiring layers has conductor patterns and an interlayer insulating film for insulation between the conductor patterns,
wherein each of the connection layers has a connection conductor piece for coupling the conductor patterns in the different wiring layers and the interlayer insulating film for insulation between the connection conductor pieces,
wherein a top wiring layer of the wiring layers has an external terminal formed by the conductor pattern and a protective insulating film covering the external terminal,
wherein the external terminal comprises a conductor including aluminum as a principal component,
wherein the protective insulating film has an opening for allowing part of the external terminal to be exposed,
wherein the external terminal has a probe contact area in apart of the area exposed from the opening of the protective insulating film,
wherein the conductor pattern is not arranged in a portion overlapping with the probe contact area in a plane in a wiring layer which is one layer lower than the top wiring layer of the wiring layers,
wherein a barrier conductor film is arranged between the external terminal and the underlying interlayer insulating film,
wherein the barrier conductor film comprises a conductor including tantalum or tantalum nitride as a principal component, and
wherein the semiconductor element is formed over a main surface of the semiconductor substrate at a position overlapping, in a plane, with the external terminal.

17. A semiconductor device according to claim 16,
wherein the barrier conductor film comprises a conductor including tantalum nitride as a principal component, and
wherein a thickness of the barrier conductor film in a vertical direction is 20 nm or greater but 200 nm or smaller.

18. A semiconductor device according to claim 17, wherein, over a portion of the external terminal exposed from the opening of the protective insulating film, the probe contact area has a probe mark having a width of 10 μm or greater.

19. A semiconductor device according to claim 18, wherein the barrier conductor film is amorphous.
